(19) United States
(12) Patent Application Publication
(10) Pub. No.: US 2015/0228776 A1
(43) Pub. Date: Aug. 13, 2015

(54) METHODS OF FORMING CONTACTS TO SEMICONDUCTOR DEVICES USING A BOTTOM ETCH STOP LAYER AND THE RESULTING DEVICES

(71) Applicant: GLOBALFOUNDRIES Inc., Grand Cayman (KY)

(72) Inventor: Ruilong Xie, Niskayuna, NY (US)

(73) Assignee: GLOBALFOUNDRIES Inc., Grand Cayman (KY)

(21) Appl. No.: 14/175,217

(22) Filed: Feb. 7, 2014

(51) Int. Cl. H01L 29/78; H01L 21/768; H01L 29/66

(52) U.S. Cl. CPC H01L 29/78; H01L 29/66477; H01L 21/768

(57) ABSTRACT

One method disclosed includes, among other things, forming a patterned high-k etch stop layer above source/drain regions, performing at least etching process to form at least one contact opening in a layer of insulating material, wherein the patterned high-k etch stop layer acts as an etch stop during the etching process, performing a second etching process to remove portions of the patterned high-k etch stop layer exposed by the contact opening and forming a conductive contact in the contact opening that is conductively coupled to the source/drain regions. The device includes a patterned high-k etch stop layer positioned between the conductive contact and an outermost sidewall spacer, wherein an outer side surface of the patterned high-k etch stop layer contacts the conductive contact.

### BACKGROUND OF THE INVENTION

1. Field of the Invention

The present disclosure generally relates to the fabrication of integrated circuits, and, more particularly, to various methods of forming contacts to semiconductor devices using a bottom etch stop layer and the resulting semiconductor devices.

2. Description of the Related Art

In modern integrated circuits, such as microprocessors, storage devices and the like, a very large number of circuit elements, especially transistors, are provided and operated on a restricted chip area. Immense progress has been made over recent decades with respect to increased performance and reduced feature sizes of circuit elements, such as transistors. However, the ongoing demand for enhanced functionality of electronic devices forces semiconductor manufacturers to steadily reduce the dimensions of the circuit elements and to increase the operating speed of the circuit elements. The continuing scaling of feature sizes, however, involves great efforts in redesigning process techniques and developing new process strategies and tools so as to comply with new design rules. Generally, in complex circuitry including complex logic portions, MOS technology is presently a preferred manufacturing technique in view of device performance and/or power consumption and/or cost efficiency. In integrated circuits including logic portions fabricated by MOS technology, field effect transistors (FETs) are provided that are typically operated in a switched mode, that is, these devices exhibit a highly conductive state (on-state) and a high impedance state (off-state). The state of the field effect transistor is controlled by a gate electrode, which controls, upon application of an appropriate control voltage, the conductivity of a channel region formed between a drain region and a source region that are formed in a substrate.

To improve the operating speed of FETs, and to increase the density of FETs on an integrated circuit device, device designers have greatly reduced the physical size of FETs over the years. More specifically, the channel length of FETs has been significantly decreased, which has resulted in improving the switching speed of FETs. However, decreasing the channel length of a FET also decreases the distance between the source region and the drain region. In some cases, this decrease in the separation between the source and the drain makes it difficult to efficiently inhibit the electrical potential of the source region and the channel from being adversely affected by the electrical potential of the drain. This is sometimes referred to as a so-called short channel effect, wherein the characteristic of the FET as an active switch is degraded.

In contrast to a FET, which has a planar structure, a so-called FinFET device has a three-dimensional (3D) or non-planar structure. In general, a FinFET device includes one or more vertically oriented fins that are formed by forming a plurality trenches in a semiconductor substrate. A gate structure is positioned around the two side surfaces and the upper surface of the fin. When an appropriate voltage is applied to the gate electrode of a FinFET device, the surfaces (and the inner portion near the surface) of the fins, i.e., the vertically oriented sidewalls and the top upper surface of the fin, form a surface inversion layer or a volume inversion layer that contributes to current conduction. In a single fin FinFET device, the “channel-width” is estimated to be about two times (2×) the vertical fin-height plus the width of the top surface of the fin, i.e., the fin width. Multiple fins can be formed in the same foot-print as that of a planar transistor device. Accordingly, for a given plot space (or foot-print), FinFETs tend to be able to generate significantly higher drive current density than planar transistor devices. Additionally, the leakage current of FinFET devices after the device is turned “OFF” is significantly reduced as compared to the leakage current of planar FETs, due to the superior gate electrostatic control of the “fin” channel on FinFET devices. The gate structures for planar FET devices as well as for non-planar FET devices, such as FinFET devices, may be manufactured using so-called “gate-first” or “replacement gate” (gate-last) manufacturing techniques.

For many early device technology generations, the gate structures of most transistor elements (planar or FinFET devices) were comprised of a plurality of silicon-based materials, such as a silicon dioxide and/or silicon oxynitride gate insulation layer, in combination with a polysilicon gate electrode. However, as the channel length of aggressively scaled transistor elements has become increasingly smaller, many newer generation devices employ gate structures that contain alternative materials in an effort to avoid the short channel effects which may be associated with the use of traditional silicon-based materials in reduced channel length transistors. For example, in some aggressively scaled transistor elements, which may have channel lengths on the order of approximately 10-32 nm or less, gate structures that include a so-called high-k dielectric gate insulation layer and one or more metal layers that function as the gate electrode (HK/MG) have been implemented. Such alternative gate structures have been shown to provide significantly enhanced operational characteristics over the heretofore more traditional silicon dioxide/polysilicon gate structure configurations.

Depending on the specific overall device requirements, several different high-k materials—i.e., materials having a dielectric constant, or k-value, of approximately 10 or greater—have been used with varying degrees of success for the gate insulation layer in an HK/MG gate electrode structure. For example, in some transistor element designs, a high-k gate insulation layer may include tantalum oxide (Ta₂O₅), hafnium oxide (HfO₂), zirconium oxide (ZrO₂), titanium oxide (TiO₂), aluminum oxide (Al₂O₃), hafnium silicates (HfSiOₓ) and the like. Furthermore, one or more non-polysilicon metal gate electrode materials—i.e., a metal gate stack—may be used in HK/MG configurations so as to control the work function of the transistor. These metal gate electrode materials may include, for example, one or more layers of titanium (Ti), titanium nitride (TiN), titanium-aluminum (TiAl), titanium-aluminum-carbon (TiALC), aluminum (Al), aluminum nitride (AlN), tantalum (Ta), tantalum nitride (TaN), tantalum carbide (TaC), tantalum carbonitride (TaCN), tantalum silicon nitride (TaSiN), tantalum silicide (TaSi) and the like.

As mentioned above, one well-known processing method that has been used for forming a transistor with a high-k/metal gate structure is the so-called “gate last” or “replacement gate” technique. The replacement gate process may be used when forming planar devices or 3D devices. FIGS. 1A-1E simplistically depict one illustrative prior art method for forming an HK/MG replacement gate structure using a replacement gate technique on a planar transistor device. As shown in FIG. 1A, the process includes the formation of a basic transistor structure above a semiconducting substrate 12 in an active area defined by a shallow trench isolation structure 13. At the point of fabrication depicted in FIG. 1A, the device 10 includes a sacrificial gate insulation layer 14, a dummy or sacrificial gate electrode 15, outermost sidewall spacers 16, a layer of insulating material 17 and source/drain regions 18 formed in the substrate 12. The various components and structures of the device 10 may be formed using a variety of different materials and by performing a variety of known techniques. For example, the sacrificial gate insulation layer 14 may be comprised of silicon dioxide, the sacrificial gate electrode 15 may be comprised of polysilicon, the sidewall spacers 16 may be comprised of silicon nitride and the layer of insulating material 17 may be comprised of silicon dioxide. The source/drain regions 18 may be comprised of implanted dopant materials (N-type dopants for NMOS devices and P-type dopants for PMOS devices) that are implanted into the substrate 12 using known masking and ion implantation techniques. Of course, those skilled in the art will recognize that there are other features of the transistor 10 that are not depicted in the drawings for purposes of clarity. For example, so-called halo implant regions are not depicted in the drawings, as well as various layers or regions of silicon/germanium that are typically found in high performance PMOS transistors. At the point of fabrication depicted in FIG. 1A, the various structures of the device 10 have been formed and a chemical mechanical polishing (CMP) process has been performed to remove any materials above the sacrificial gate electrode 15 (such as a protective cap layer (not shown) comprised of silicon nitride) so that at least the sacrificial gate electrode 15 may be removed.

As shown in FIG. 1B, one or more etching processes are performed to remove the sacrificial gate electrode 15 and the sacrificial gate insulation layer 14 to thereby define a gate cavity 20 where a replacement gate structure will subsequently be formed. Typically, the sacrificial gate insulation layer 14 is removed as part of the replacement gate technique, as depicted herein. However, the sacrificial gate insulation layer 14 may not be removed in all applications.

Next, as shown in FIG. 1C, various layers of material that will constitute a replacement gate structure 30 are formed in the gate cavity 20. Even in cases where the sacrificial gate insulation layer 14 is intentionally removed, there will typically be a very thin native oxide layer (not shown) that forms on the substrate 12 within the gate cavity 20. The materials used for the replacement gate structures 30 for NMOS and PMOS devices are typically different. For example, the replacement gate structure 30 for an NMOS device may be comprised of a high-k gate insulation layer 30A, such as hafnium oxide, having a thickness of approximately 2 nm, a first metal layer 30B (e.g., a layer of titanium nitride with a thickness of about 1-2 nm), a second metal layer 30C—a so-called work function adjusting metal layer for the NMOS device—(e.g., a layer of titanium-aluminum or titanium-aluminum-carbon with a thickness of about 5 nm), a third metal layer 30D (e.g., a layer of titanium nitride with a thickness of about 1-2 nm) and a bulk metal layer 30E, such as aluminum or tungsten.

Ultimately, as shown in FIG. 1D, one or more CMP processes are performed to remove excess portions of the gate insulation layer 30A, the first metal layer 30B, the second metal layer 30C, the third metal layer 30D and the bulk metal layer 30E positioned outside of the gate cavity 20 to thereby define the replacement gate structure 30 for an illustrative NMOS device. Typically, the replacement gate structure 30 for a PMOS device does not include as many metal layers as does an NMOS device. For example, the gate structure 30 for a PMOS device may only include the high-k gate insulation layer 30A, a single layer of titanium nitride—the work function adjusting metal for the PMOS device—having a thickness of about 3-4 nm, and the bulk metal layer 30E.

FIG. 1E depicts the device 10 after several process operations were performed. First, one or more etching processes were performed to remove upper portions of the various materials within the cavity 20 so as to form a recess within the gate cavity 20. Then, a gate cap layer 31 was formed in the recess above the recessed gate materials. The gate cap layer 31 is typically comprised of silicon nitride and it may be formed by depositing a layer of gate cap material so as to over-fill the recess formed in the gate cavity and, thereafter, performing a CMP process to remove excess portions of the gate cap material layer positioned above the surface of the layer of insulating material 17. The gate cap layer 31 is formed so as to protect the underlying gate materials during subsequent processing operations.

Irrespective of whether a planar or non-planar device is considered, electrical connections must be formed to the device so that it may operate as intended. That is, electrical connection must be made to the source region, the drain region and the gate electrode of the device. Typically, the conductive structures that actually make contact with the device itself, i.e., the source region, the drain region and the gate electrode, are referred to as “contacts” within the industry. Such conductive contacts are formed in one or more layers of insulating material. The entire arrangement of the conductive contacts and the associated layer(s) of insulating material is sometimes referred to as the “contact level” of the overall electrical “wiring arrangement” that is formed to provide electrical connection to the integrated circuit device.

Typically, due to the large number of circuit elements and the required complex layout of modern integrated circuits, the electrical connections of the individual circuit elements cannot be established within the same device level on which the circuit elements are manufactured, but require one or more additional metallization layers, which generally include metal-containing lines providing the intra-level electrical connection, and also include a plurality of inter-level connections or vertical connections, which are also referred to as vias. A modern integrated circuit product will typically comprise several metallization layers, e.g., multiple layers of conductive vias and conductive lines. The M1 metallization layer is typically the first major “wiring” layer that is formed on the product. As device dimensions have decreased, the conductive contact elements in the contact level have to be provided with critical dimensions in the same order of magnitude. The contact elements typically represent plugs, which are formed of an appropriate metal or metal composition, wherein, in sophisticated semiconductor devices, tungsten, in combination with appropriate barrier materials, has proven to be a viable contact metal. For this reason, contact technologies have been developed in which contact openings are formed in a self-aligned manner by removing dielectric material, such as silicon dioxide, selectively from the spaces between closely spaced gate electrode structures. That is, after completing the transistor structure, the gate electrode structures are used as etch masks for selectively removing the silicon dioxide material in order to expose the source/drain regions of the transistors, thereby providing self-aligned trenches which are substantially laterally delineated by the spacer structures of the gate electrode structures.

However, the aforementioned process of forming self-aligned contacts results in an undesirable loss of the materials that protect the conductive gate electrode, i.e., the gate cap layer and the sidewall spacers, as will be explained with reference to FIGS. 2A-2B. FIG. 2A schematically illustrates a cross-sectional view of an integrated circuit product 40 at an advanced manufacturing stage. As illustrated, the product 40 comprises a plurality of illustrative gate structures 41 that are formed above a substrate 42, such as a silicon substrate. The gate structures 41 are comprised of an illustrative gate insulation layer 43 and an illustrative gate electrode 44 that are formed in a gate cavity using a gate-last processing technique. An illustrative gate cap layer 46 and sidewall spacers 48 encapsulate and protect the gate structures 41. The gate cap layer 46 and sidewall spacers 48 are typically made of silicon nitride. Also depicted in FIG. 2A are a plurality of raised source/drain regions 50 and a layer of insulating material 52, e.g., silicon dioxide. FIG. 2B depicts the product 40 after a contact opening 54 has been formed in the layer of insulating material 52 for a self-aligned contact. Although the contact etch process performed to form the opening 54 is primarily directed at removing the desired portions of the layer of insulating material 52, portions of the protective gate cap layer 46 and the protective sidewall spacers 48 get consumed during the contact etch process, as simplistically depicted in the dashed regions 56. Given that the cap layer 46 and the spacers 48 are attacked in the contact etch process, the thickness of these protective materials must be sufficient such that, even after the contact etch process is completed, there remains sufficient cap layer material and spacer material to protect the gate structures 41. Accordingly, device manufacturers tend to make the cap layers 46 and spacers 48 “extra thick,” i.e., with an additional thickness that may otherwise not be required but for the consumption of the cap layers 46 and the spacers 48 during the contact etch process. In turn, increasing the thickness of such structures, i.e., increasing the thickness of the gate cap layers 46, causes other problems, such as increasing the aspect ratio of the contact opening 54 due to the increased height, increasing the initial gate height, which makes the gate etching and spacer etching processes more difficult, etc.

As device dimensions continue to shrink, self-aligned contacts are needed to prevent an electrical short between the gate and the source/drain contact element. As noted above, in prior art processing techniques, a relatively thick gate cap layer 46 (e.g., silicon nitride) is formed to protect the underlying metal layers in the gate electrode 44 from being exposed during the source/drain contact etch process which results in the formation of the contact opening 54 (see FIGS. 2A-2B). If the gate electrode materials are exposed during the contact etch process, then an electrical short will be formed between the gate electrode 44 and the source/drain contact element (not shown) that will be formed in the contact opening 54.

Another problem associated with forming contacts to the source/drain regions of the device 40 relates to the unwanted attack of epitaxially formed semiconductor material and/or the exposed surfaces of the substrate (in cases where epi material is not formed) in the source/drain regions of the device 40, i.e., in the depicted example, the raised source/drain regions 50. In many applications, but not all, epi semiconductor material is formed as part of the source/drain region, either in a cavity formed in the substrate or above the surface of the substrate. In the typical contact formation process, patterned layers of photoresist are formed above the substrate to form openings in layers of insulating material. A so-called “ashing” plasma-based process is typically performed to remove the patterned layers of photoresist material. Unfortunately, absent some form of protection, the epi semiconductor material and/or the surfaces of the substrate is typically exposed to several ashing processing in the contact formation processing sequence, which undesirably attacks the exposed portions of the epi semiconductor material and/or the surfaces of the substrate in the source/drain regions of the device.

The present disclosure is directed to various methods of forming contacts to semiconductor devices using a bottom etch stop layer and the resulting semiconductor devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods of forming contacts to semiconductor devices using a bottom etch stop layer and the resulting semiconductor devices. One method disclosed includes, among other things, forming a patterned high-k etch stop layer above an epitaxially formed semiconductor material in the source/drain regions of the device, forming at least one layer of insulating material above the patterned high-k etch stop layer, performing at least one contact opening etching process to form at least one contact opening in the at least one layer of insulating material, wherein the patterned high-k etch stop layer acts as an etch stop during the at least one contact opening etching process, performing an etching process to remove portions of the patterned high-k etch stop layer exposed by the at least one contact opening and forming a conductive contact in the at least one contact opening that is conductively coupled to the epitaxially formed semiconductor material in at least one of the source/drain regions of the device.

Another illustrative method disclosed herein includes, among other things, forming a high-k etch stop layer above the gate structure and above an epitaxially formed semiconductor material in the source/drain regions of the device, forming a sacrificial layer of material above the gate structure and the high-k etch stop layer, reducing a thickness of the sacrificial layer of material so as to expose a portion, but not all, of the high-k etch stop layer, performing at least one first etching process to remove at least the portions of the high-k etch stop layer positioned above the upper surface of the reduced-thickness sacrificial layer, thereby forming a patterned high-k etch stop layer, after performing the at least one first etching process, removing any residual portions of the reduced-thickness sacrificial layer of material, after removing the residual portions of the reduced-thickness sacrificial layer of material, forming at least one layer of insulating material above the patterned high-k etch stop layer, performing at least one second contact opening etching process to form at least one contact opening in the at least one layer of insulating material, wherein the patterned high-k etch stop layer acts as an etch stop during the at least one second contact opening etching process, performing a third etching process to remove portions of the patterned high-k etch stop layer exposed by the at least one contact opening and forming a conductive contact in the at least one contact opening that is conductively coupled to the epitaxially formed semiconductor material in at least one of the source/drain regions of the device.

Yet another illustrative method disclosed herein includes, among other things, forming a patterned high-k etch stop layer above the source/drain regions of the device, forming at least one layer of insulating material above the patterned high-k etch stop layer, performing at least one contact opening etching process to form at least one contact opening in the at least one layer of insulating material, wherein the patterned high-k etch stop layer acts as an etch stop during the at least one contact opening etching process, performing an etching process to remove portions of the patterned high-k etch stop layer exposed by the at least one contact opening and forming a conductive contact in the at least one contact opening that is conductively coupled to at least one of the source/drain regions of the device.

One illustrative device disclosed herein includes, among other things, at least a gate structure formed above a semiconductor substrate, a gate cap layer positioned above at least a portion of the gate structure, an outermost sidewall spacer formed adjacent a side of the gate structure, a conductive contact that is conductively coupled to one of the source/drain regions and a patterned high-k etch stop layer positioned between the conductive contact and the outermost sidewall spacer, wherein an outer side surface of the patterned high-k etch stop layer contacts the conductive contact and an upper surface of the patterned high-k etch stop layer is positioned at a level relative to an upper surface of the substrate that is below a level of the bottom surface of the gate cap layer.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1E depict one illustrative prior art method of forming a gate structure of a transistor using a so-called “replacement gate” technique;

FIGS. 2A-2B schematically illustrate a cross-sectional view of an illustrative prior art integrated circuit product that employs self-aligned contacts; and

FIGS. 3A-3N depict various illustrative methods disclosed herein for forming contacts to semiconductor devices using a bottom etch stop layer and the resulting semiconductor devices.

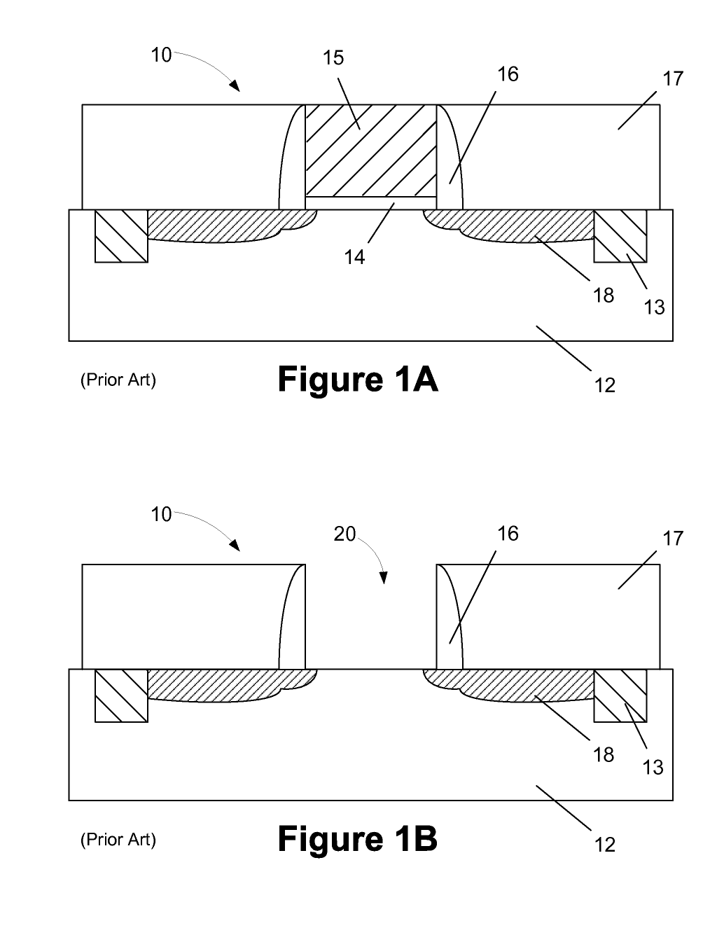

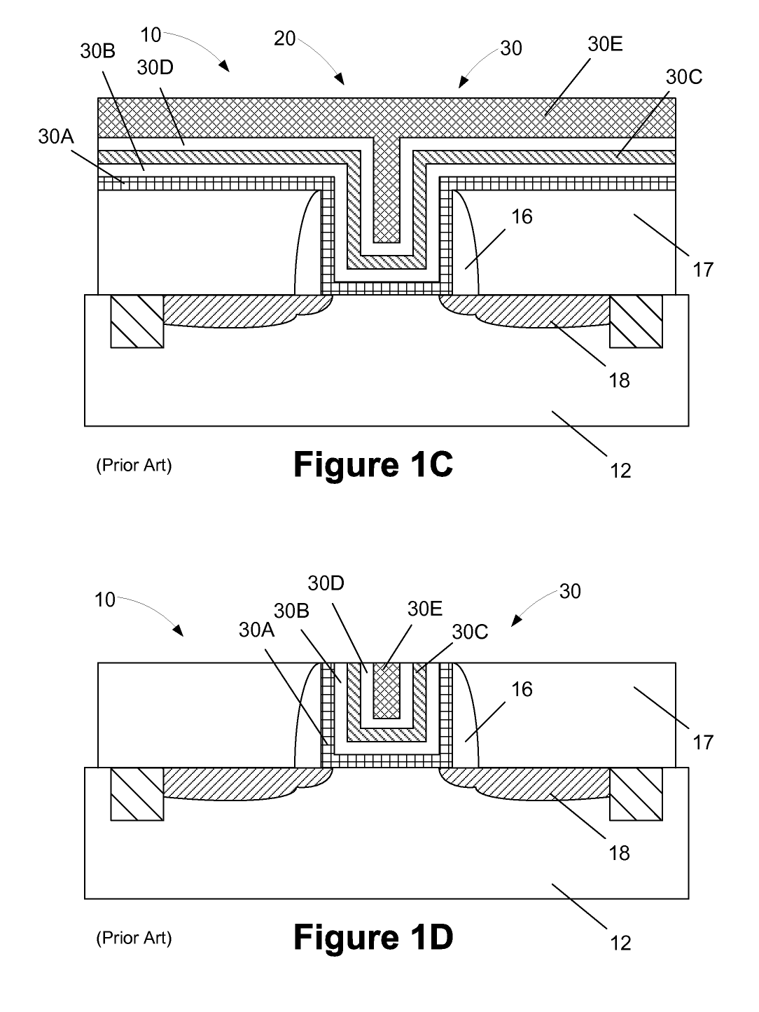

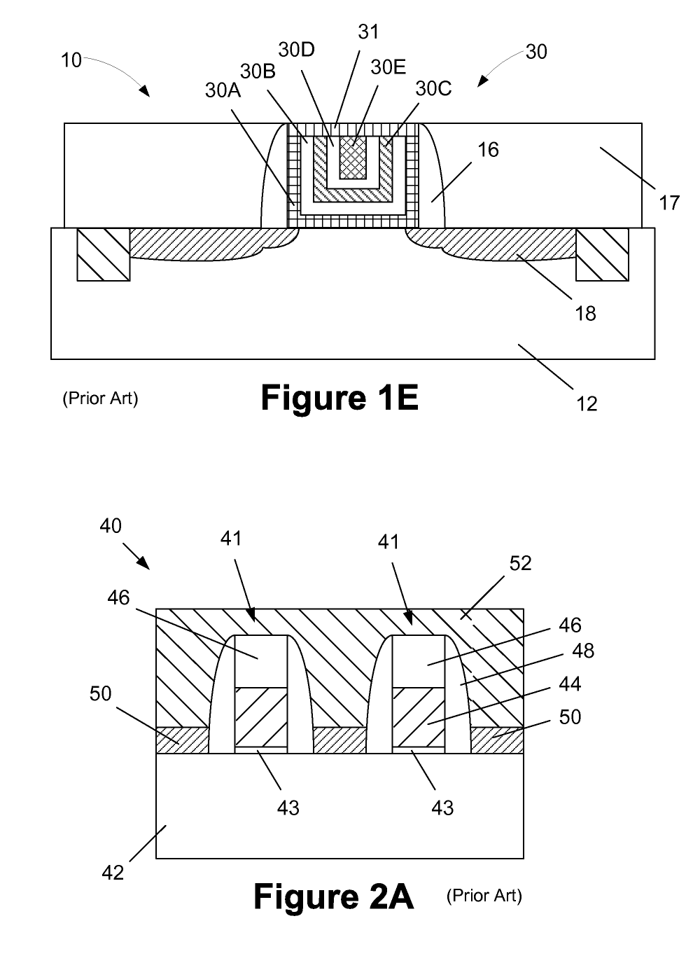

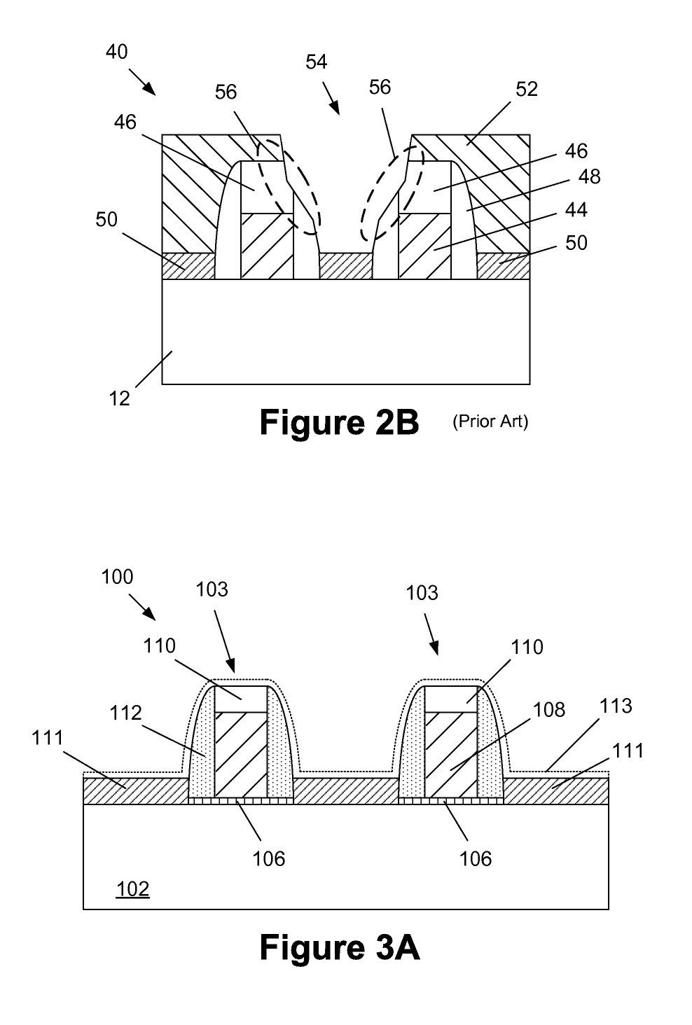

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure generally relates to various methods of forming contacts to semiconductor devices using a bottom etch stop layer and the resulting semiconductor devices. Moreover, as will be readily apparent to those skilled in the art upon a complete reading of the present application, the present method is applicable to a variety of devices, including, but not limited to, logic devices, memory devices, etc., and the methods disclosed herein may be employed to form N-type or P-type semiconductor devices. The methods and devices disclosed herein may be employed in manufacturing products using a variety of technologies, NMOS, PMOS, CMOS, etc., and they may be employed in manufacturing a variety of different devices, e.g., memory devices, logic devices, ASICs, etc.

As will be appreciated by those skilled in the art after a complete reading of the present application, the inventions disclosed herein may be employed in forming integrated circuit products using planar transistor devices, as well as so-called 3D devices, such as FinFETs, or a combination of such devices. For purposes of disclosure, reference will be made to an illustrative process flow wherein an integrated circuit product is formed with a plurality of planar transistor devices. However, the inventions disclosed herein should not be considered to be limited to such an illustrative example. With reference to the attached figures, various illustrative embodiments of the methods and devices disclosed herein will now be described in more detail.

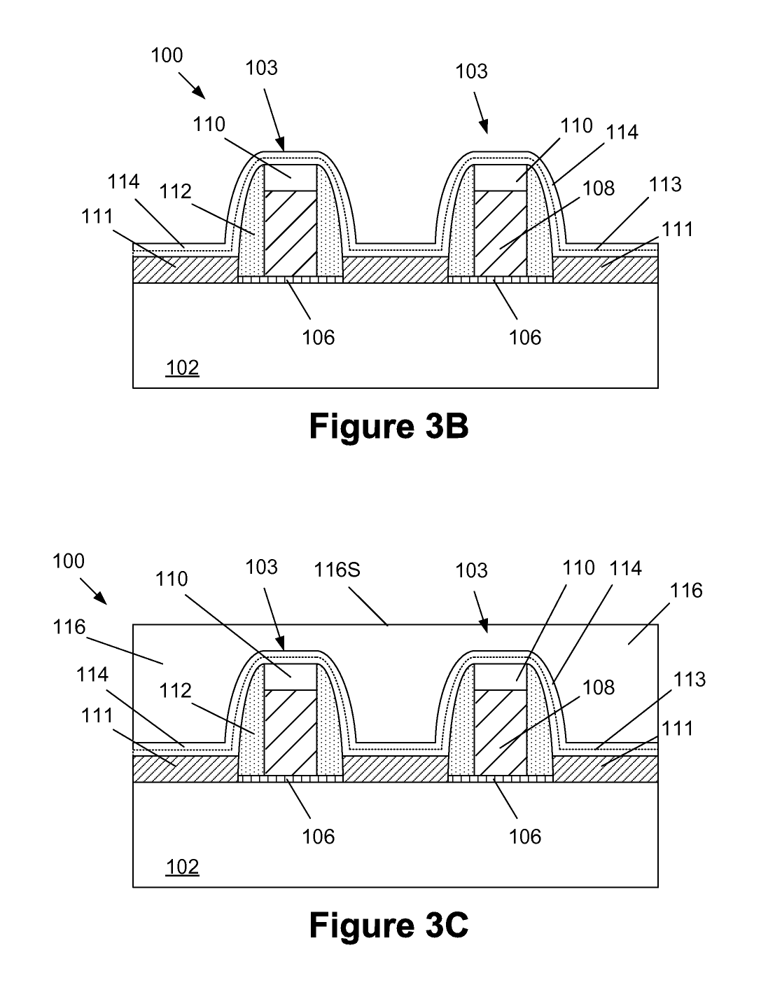

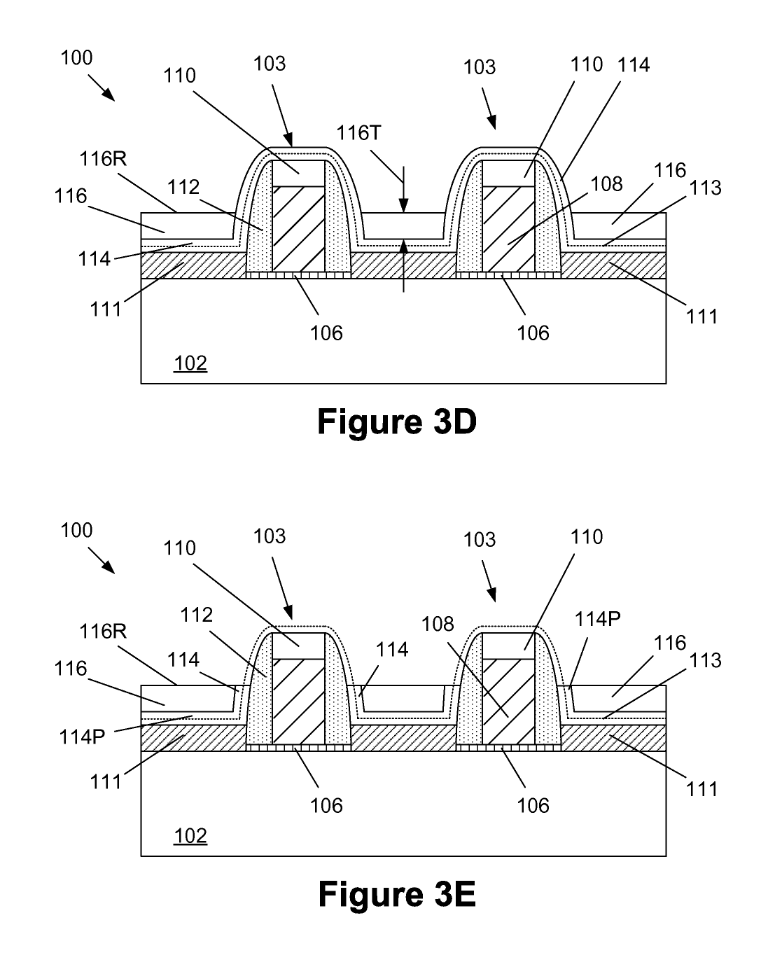

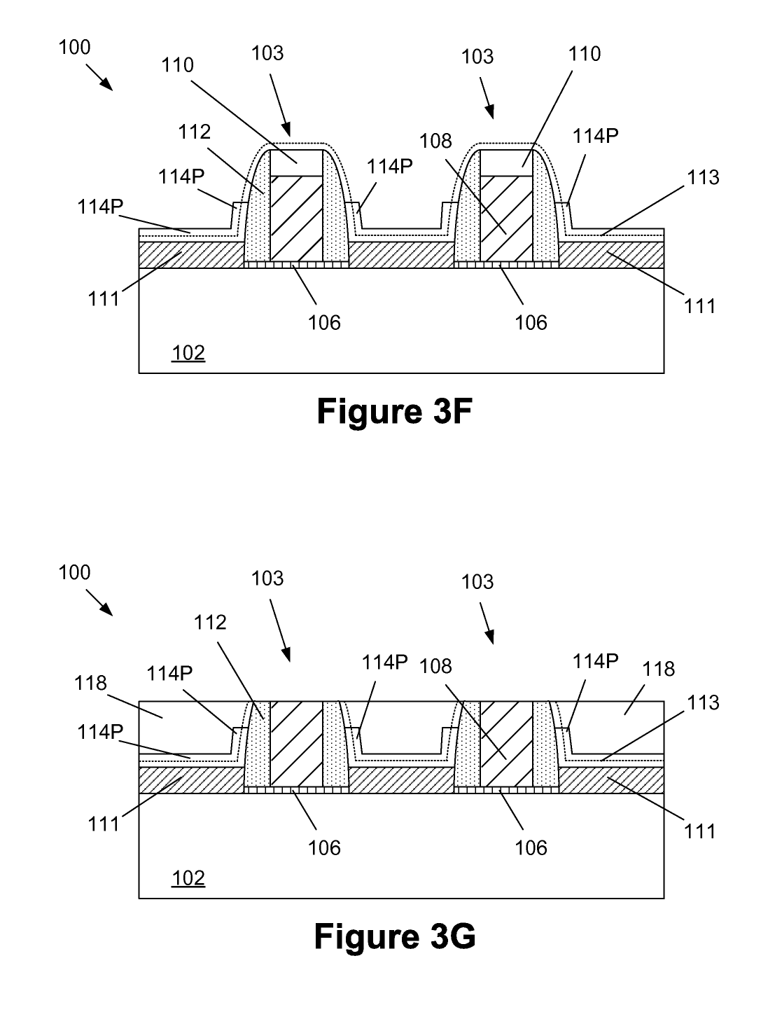

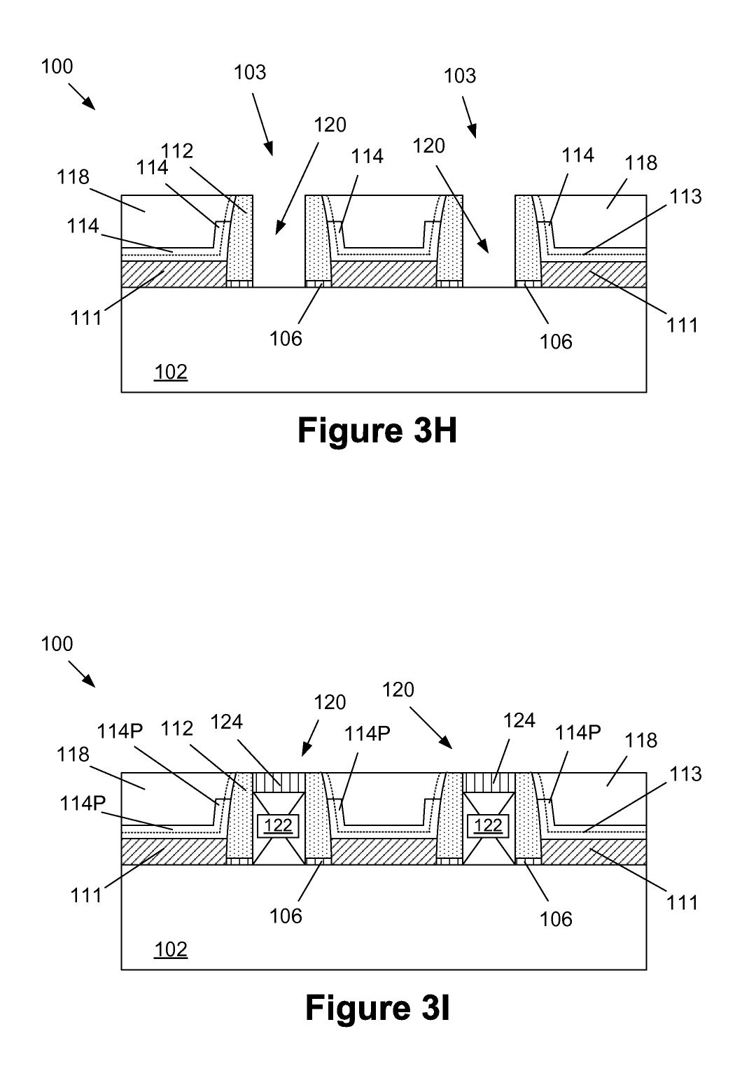

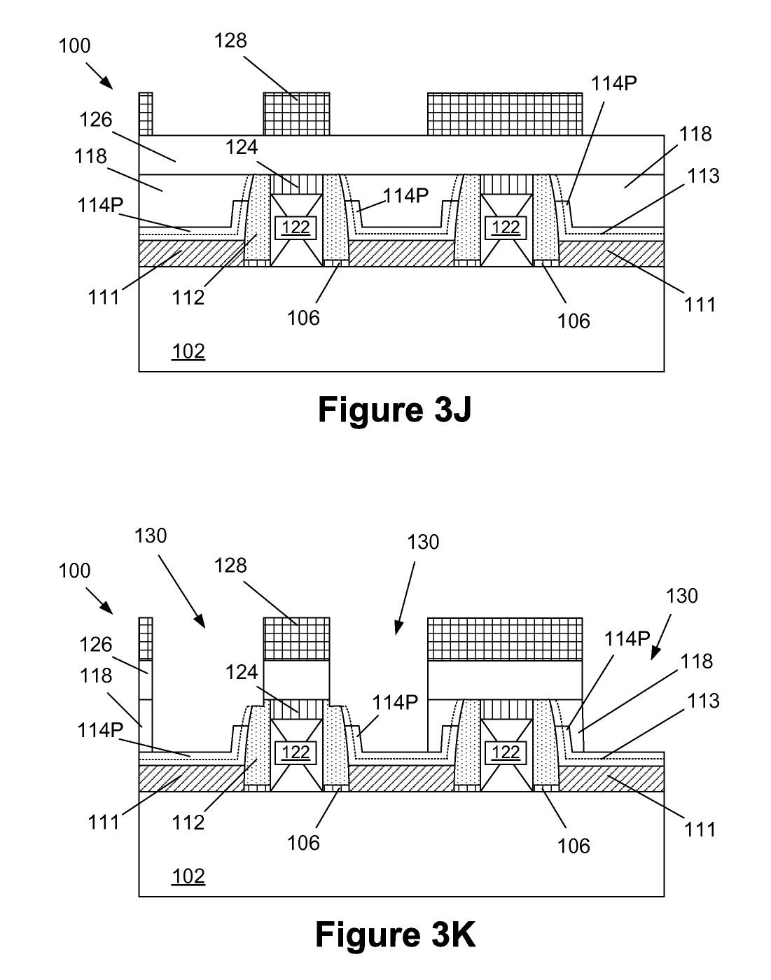

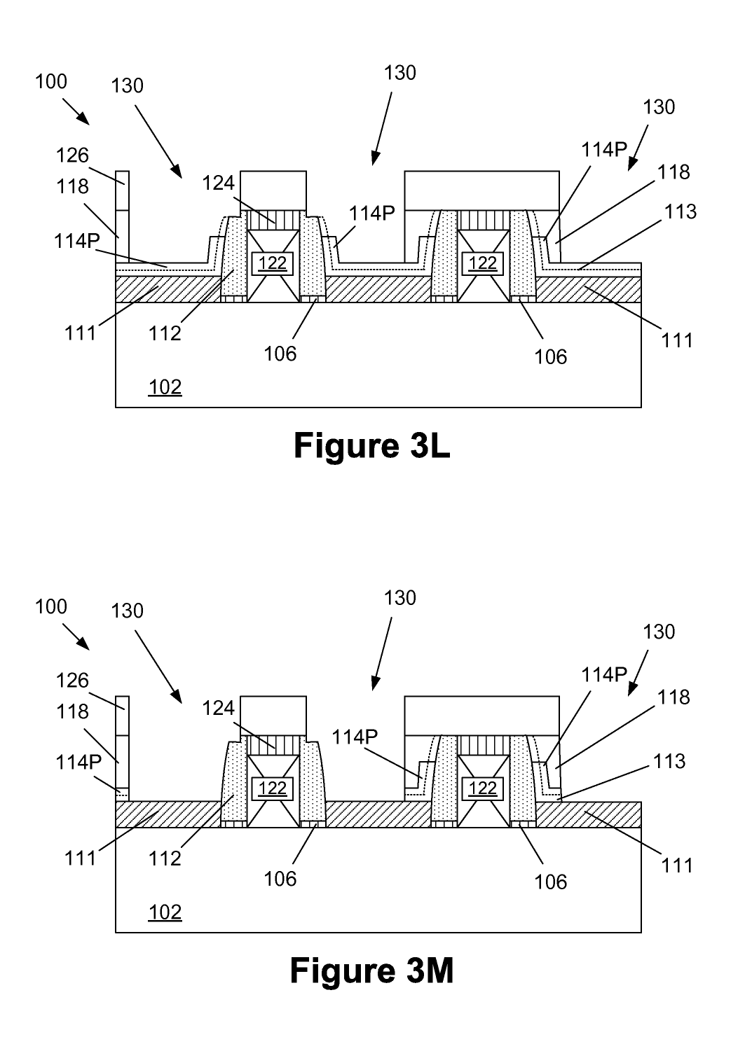

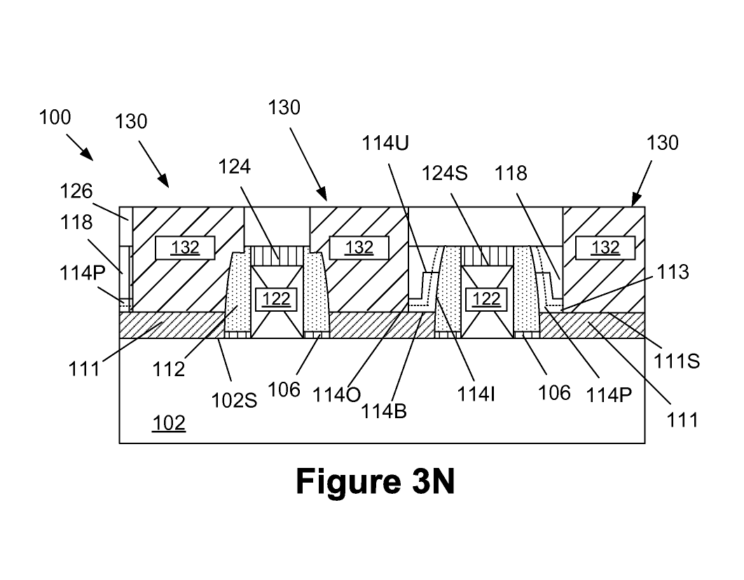

FIGS. 3A-3N depict one illustrative method disclosed herein for forming contacts to semiconductor devices using a bottom etch stop layer and the resulting semiconductor devices 100. FIG. 3A is a simplified view of the illustrative integrated circuit product 100 at an early stage of manufacturing, wherein a pair of illustrative transistors will be formed in and above the semiconductor substrate 102. So as not to obscure the inventions disclosed herein, isolation regions that are formed in the substrate 102 to define active regions where the transistors will be formed are not depicted in the attached drawings. The transistors may be either NMOS or PMOS transistors or one of each type. Additionally, various doped regions, e.g., source/drain regions, halo implant regions, well regions and the like, are also not depicted in the attached drawings. The substrate 102 may have a variety of configurations, such as the depicted bulk silicon configuration. The substrate 102 may also have a silicon-on-insulator (SOI) configuration that includes a bulk silicon layer, a buried insulation layer and an active layer, wherein semiconductor devices are formed in and above the active layer. The substrate 102 may be made of silicon or it may be made of materials other than silicon. Thus, the terms “substrate” or “semiconductor substrate” should be understood to cover all semiconducting materials and all forms of such materials.

In the example disclosed herein, the transistors will be formed using a replacement gate technique, but the invention is not limited to transistors wherein such replacement gate structures are formed. That is, the inventions disclosed herein may be employed in cases where the gate structure of the device is formed using so-called gate-first processing techniques. Accordingly, FIG. 3A depicts the product 100 at a point in fabrication wherein sacrificial gate structures 103 have been formed above the substrate 102. Also depicted are illustrative gate hard mask layers 110 (gate cap layers), outermost sidewall spacers 112 and a plurality of raised source/drain regions 111. The gate hard mask layers 110 and the sidewall spacers 112 are typically made of silicon nitride. At this point in the replacement gate process flow, an anneal process would have already been performed to activate the implanted dopant materials and repair any damage to the substrate 102 due to the various ion implantation processes that were performed. The sacrificial gates structures 103 include a sacrificial gate insulation layer 106 and a dummy or sacrificial gate electrode 108. The various components and structures of the product 100 may be formed using a variety of different materials and by performing a variety of known techniques. For example, the sacrificial gate insulation layer 106 may be comprised of silicon dioxide and the sacrificial gate electrode 108 may be comprised of polysilicon. The layers of material depicted in FIG. 3A, as well as the layers of material described below, may be formed by any of a variety of different known techniques, e.g., a chemical vapor deposition (CVD) process, an atomic layer deposition (ALD) process, a thermal growth process, spin-coating techniques, etc. The illustrative raised source/drain regions 111 may be formed in the substrate using traditional techniques, e.g., formation of cavities in the substrate 102 that are self-aligned to the spacers 112, epi deposition of a semiconductor material in the cavities, doping, etc. However, it should be understood that the presently disclosed inventions may be practiced on transistor devices that have regular or planar source/drain regions, i.e., source/drain regions that do not have any epi semiconductor material formed in or above the substrate 102. Moreover, as used herein and in the attached claims, the word “adjacent” is to be given a broad interpretation and should be interpreted to cover situations where one feature actually contacts another feature or is in close proximity to that other feature. For example, with reference to FIG. 3A, the sidewall spacers 112 are formed either adjacent to the gate electrode 108 or they may contact the gate electrode 108. Also depicted in FIG. 3A is an optional liner layer 113 (shown in dashed lines) that may be comprised of silicon nitride. If employed, such a liner layer 113 may be formed by performing a conformal deposition process and it may have a thickness that falls within the range of about 2-6 nm.

FIG. 3B depicts the device after a high-k etch stop layer 114 has been conformally deposited above the device 100. As used herein and in the attached claims, the phrase “high-k etch stop layer” shall mean an etch stop layer with a k-value of 8 or greater. In general, the high-k etch stop layer 114 should be made of a material that may be selectively etched with respect to the material of the sidewall spacers 112, the epi semiconductor material 111 and the material of the liner layer 113 (if employed). In one illustrative embodiment, the high-k etch stop layer 114 may be comprised of hafnium oxide, aluminum oxide, ZrO₂, etc., and it may be formed to a thickness that falls within the range of about 3-6 nm.

FIG. 3C depicts the device 100 after a sacrificial material layer 116 has been formed on the device 100. In one embodiment, the sacrificial material layer 116 is formed such that its upper surface 116S is positioned above the uppermost portions of the high-k etch stop layer 114, i.e., the sacrificial material layer 116 is formed such that it overfills the space between the adjacent transistors. In one illustrative embodiment, the sacrificial material layer 116 may be comprised of OPL (Optical Planarization Layer), DUO™ oxide, etc. and it may be formed using traditional techniques for forming such materials, e.g., spin-coating, deposition, etc.

FIG. 3D depicts the product 100 after a recess etching process was performed on the sacrificial material layer 116 such that it has a recessed upper surface 116R. After such recessing, the recessed sacrificial material layer 116 exposes portions, but not all, of the high-k etch stop layer 114. The amount of the recessing depends upon the particular application. In one illustrative embodiment, the recessed sacrificial material layer 116 may have a post-recessing thickness 116T that falls within the range of about 10-40 nm. In general, the recessed sacrificial material layer 116 should be recessed a sufficient amount so that sufficient portions of the high-k etch stop layer 114 may be removed (as described more fully below) so that the high-k etch stop layer 114 positioned above the gate cap layer 110 will not interfere with the gate removal process, as also described more fully below. Additionally, removing portions of the high-k etch stop layer 114 is also beneficial to the overall contact-to-gate capacitance, such that the RC delay of the circuit would be reduced by doing so, which increases the circuit operating speed.

FIG. 3E depicts the device 100 after an etching process was performed to remove the exposed portions of the high-k etch stop layer 114 selectively relative to the liner layer 113 (if employed), the sidewall spacers 112 and the gate cap layers 110. This results in the definition of a patterned high-k etch stop layer 114P. In one illustrative embodiment, the etching process performed to remove the exposed portions of the high-k etch stop layer 114 may be a wet etching process using, for example, an HF/HCl solution. The recessed sacrificial material layer 116 protects the underlying portions of the high-k etch stop layer 114 during the etching process.

FIG. 3F depicts the device after the remaining portions of the recessed sacrificial material layer 116 were removed. In one embodiment, such removal may be accomplished by performing a stripping or etching process, depending upon the material selected for the sacrificial material layer 116.

FIG. 3G depicts the product 100 after several process operations were performed. First, a layer of insulating material 118, e.g., silicon dioxide, was blanket-deposited on the device 100 using traditional manufacturing techniques, e.g., CVD. Thereafter, one or more planarization processes were performed on the layer of insulating material 118/gate cap layers 110 so as to effectively remove the gate cap layers 110 and expose at least the sacrificial gate electrodes 108. In one illustrative embodiment, the planarization process may be a chemical mechanical planarization (CMP) process that stops on the sacrificial gate electrodes 108.

FIG. 3H depicts the product 100 after several process operations, e.g., one or more wet or dry etching processes, were performed to remove the sacrificial gate electrode 108 and the sacrificial gate insulation layers 106 to thereby define gate cavities 120 where replacement gate structures will subsequently be formed for the transistors. Typically, the sacrificial gate insulation layer 106 is removed as part of the replacement gate technique, as depicted herein. However, the sacrificial gate insulation layer 106 may not be removed in all applications. Even in cases where the sacrificial gate insulation layer 106 is intentionally removed, there will typically be a very thin native oxide layer (not shown) that forms on the substrate 102 within the gate cavities 120.

FIG. 3I depicts the product after several process operations were performed. First, a pre-clean process was performed in an attempt to remove all foreign materials from within the gate cavities 120 prior to forming the various layers of material that will become part of the replacement gate structures. Thereafter, several known processing operations were performed to form a schematically depicted replacement gate structure 122 in each of the gate cavities 120. Then, one or more etching processes were performed to remove upper portions of the various materials within the cavity 120 so as to form a recess within the gate cavity 120. Thereafter, the illustrative gate cap layers 124 were formed in the recess above the recessed gate materials. The gate cap layers 124 are typically comprised of silicon nitride and they may be formed by depositing a layer of gate cap material so as to over-fill the recess formed in the gate cavity 120 and, thereafter, performing a CMP process to remove excess portions of the gate cap material layer positioned above the surface of the layer of insulating material 118. The gate cap layers 124 are formed so as to protect the underlying gate materials during subsequent processing operations.

The replacement gate structures 122 depicted herein are intended to be representative in nature of any type of gate structure that may be employed in manufacturing integrated circuit products using so-called gate-last (replacement-gate) manufacturing techniques. The replacement gate structure 122 typically comprises a high-k (k value greater than 10) gate insulation layer (not individually shown), such as hafnium oxide, one or more metal layers (not individually shown) (e.g., layers of titanium nitride or TiAlC depending upon the type of transistor device being manufactured), and a bulk conductive material layer, such as tungsten or aluminum. However, after a complete reading of the present application, those skilled in the art will appreciate that the methods and devices disclosed herein are not limited to the particular configuration of the materials used to initially form the replacement gate structures 122 or to the manner in which the replacement gate structures 122 are initially formed.

The next major processing sequence involves formation of the device level contacts for the product 100. Accordingly, FIG. 3J depicts the product 100 after several processing operations were performed. First, another layer of insulating material 126, e.g., silicon dioxide, a low-k material (k-value less than about 3.3), etc., was deposited above the product 100. Thereafter, a patterned etch mask layer 128, e.g., a layer of photoresist material, was formed above the device 100 using traditional photolithography tools and equipment. In one embodiment, the layer of insulating material 126 may be a layer of silicon dioxide that is formed by performing a CVD process. The layer of insulating material 126 may be formed to any desired thickness. Note that, in the depicted example, there is some misalignment between the openings in the patterned masking layer 128 and the desired location of the contact openings, i.e., the openings in the patterned etch mask layer 128 are positioned above portions of the gate cap layer 124 and the sidewall spacers 126.

FIG. 3K depicts the product 100 after one or more etching processes were performed on the product 100 through the patterned etch mask 128 to remove portions of the layers of insulating material 126, 118 and thereby define an illustrative contact opening 130. During the etching process, the remaining portions of the patterned high-k etch stop layer 114P protects the underling epi material of the raised source/drain region 111.

FIG. 3L depicts the device 100 after an ashing process has been performed to remove the patterned etch mask 128. During the ashing process, the remaining portions of the patterned high-k etch stop layer 114P protect the underling epi material of the raised source/drain region 111 and/or the underlying substrate 102 (in the case where no epi material is formed). As will be appreciated by those skilled in the art after a complete reading of the present application, the patterned high-k etch stop layer 114P may be left in position until all ashing processes have been performed. For example, in some cases, the contact openings for the source/drain contacts may be formed at a different point in time than the contact openings that are formed to contact the gate structure. In fact, formation of the gate contacts may involve formation and use of another separate patterned masking layer (not shown). In such a situation, the typical process flow would involve formation of the actual conductive source/drain contacts and the conductive gate contact in a common processing sequence that involves deposition of the necessary conductive materials in all of the contact openings and thereafter performing a CMP process to remove excess materials. In such a case, absent use of the inventions disclosed herein, the epi material 111 and/or the underlying substrate 102 (in the case where no epi material is formed) may be exposed to at least two separate ashing processes.

FIG. 3M depicts the product 100 after several process operations were performed. First, an etching process was performed on the product 100 to remove the exposed portions of the patterned high-k etch stop layer 114P. If the liner layer 113 is employed, this etching process may stop on the underling liner layer 113. Thereafter, a second etching process would be performed to remove the exposed portions of the liner layer 113 to expose the underlying epi semiconductor material in the source/drain regions 111 and/or the underlying substrate 102 (in the case where no epi material is formed). If the liner layer 113 is not employed, then the first etching process would expose the underlying epi semiconductor material in the source/drain regions 111 and/or the underlying substrate 102 (in the case where no epi material is formed).

FIG. 3N depicts the product 100 after a plurality of illustrative conductive contact structures 132 have been formed in the contact openings 130 such that they are conductively coupled to the epi material in the source/drain regions 111. The contact structure 132 is intended to be schematic and representative in nature, as it may be formed using any of a variety of different conductive materials and by performing traditional manufacturing operations. The contact structure 132 may also contain one or more barrier layers (not depicted). In one illustrative example, the contact structure 132 may be formed by depositing a liner, e.g., a titanium nitride liner, followed by overfilling the self-aligned contact openings 130 with a conductive material, such as tungsten. Thereafter, a CMP process may be performed to planarize the upper surface of the layer of insulating material 126, which results in the removal of excess portions of the liner and the tungsten positioned above the layer of insulating material 126 outside of the contact opening 130 and the formation of the contact structures 132. If desired, a metal silicide material (not shown) may be formed on the source/drain regions 111 prior to forming the contact structures 132.

As will be appreciated and understood by those skilled in the art after a complete reading of the present application, there are several novel methods and devices disclosed herein. One method disclosed includes, among other things, forming a patterned high-k etch stop layer 114P above an epitaxially formed semiconductor material in the source/drain regions 111 of the device 100, forming at least one layer of insulating material 118 above the patterned high-k etch stop layer 114P, performing at least one contact opening etching process to form at least one contact opening 130 in the at least one layer of insulating material 118, wherein the patterned high-k etch stop layer 114P acts as an etch stop during the at least one contact opening etching process, performing an etching process to remove portions of the patterned high-k etch stop layer 114P exposed by the at least one contact opening 130 and forming a conductive contact 132 in the at least one contact opening 130 that is conductively coupled to the epitaxially formed semiconductor material in at least one of the source/drain regions 111 of the device 100.

Another illustrative method disclosed herein includes, among other things, forming a high-k etch stop layer 114 above a gate structure 122 and above an epitaxially formed semiconductor material in the source/drain regions 111 of the device 100, forming a sacrificial layer of material 116 above the gate structure 122 and the high-k etch stop layer 114, reducing a thickness of the sacrificial layer of material 116 so as to expose a portion, but not all, of the high-k etch stop layer 114, performing at least one first etching process to remove at least the portions of the high-k etch stop layer 114 positioned above the upper surface of the reduced-thickness sacrificial layer 116, thereby forming a patterned high-k etch stop layer 114P, after performing the at least one first etching process, removing any residual portions of the reduced-thickness sacrificial layer of material 116, after removing the residual portions of the reduced-thickness sacrificial layer of material 116, forming at least one layer of insulating material 118 above the patterned high-k etch stop layer 114P, performing at least one second contact opening etching process to form at least one contact opening 130 in the at least one layer of insulating material 118, wherein the patterned high-k etch stop layer 114P acts as an etch stop during the at least one second contact opening etching process, performing a third etching process to remove portions of the patterned high-k etch stop layer 114P exposed by the at least one contact opening 130 and forming a conductive contact 132 in the at least one contact opening 130 that is conductively coupled to the epitaxially formed semiconductor material in at least one of the source/drain regions 111 of the device 100.

Yet another illustrative method disclosed herein includes, among other things, forming a patterned high-k etch stop layer 114P above the source/drain regions (i.e., without epi material) of the device 100, forming at least one layer of insulating material 118 above the patterned high-k etch stop layer 114P, performing at least one contact opening etching process to form at least one contact opening 130 in the at least one layer of insulating material 118, wherein the patterned high-k etch stop layer 114P acts as an etch stop during the at least one contact opening etching process, performing an etching process to remove portions of the patterned high-k etch stop layer 114P exposed by the at least one contact opening 130 and forming a conductive contact 132 in the at least one contact opening 130 that is conductively coupled to the source/drain regions of the device 100.

As will be appreciated and understood by those skilled in the art after a complete reading of the present application, due to the potential for misalignment of etch mask layers during the contact formation process, there may be situations wherein, after the contact 132 is formed, the residual portions of the patterned high-k etch stop layer 114P may only be present on one side of the gate structure of the device 100. In other cases, the residual portions of the patterned high-k etch stop layer 114P may be present on both sides of the gate structure 122 after the contact 132 is formed. Thus, in this application, the device will be disclosed and claimed by only looking at one side of the transistor. Of course, if residual portions of the patterned high-k etch stop layer 114P are present on both sides of the gate structure, then such a device would be covered by the attached claims.

Accordingly, with reference to FIG. 3N, one illustrative device 100 disclosed herein includes, among other things, at least a gate structure 122 formed above a semiconductor substrate 102, a gate cap layer 124 positioned above at least a portion of the gate structure 122, an outermost sidewall spacer 112 formed adjacent a side of the gate structure 122, an epi semiconductor material formed as part of the source/drain regions 111 of the device, a conductive contact 132 that is conductively coupled to one of the source/drain regions 111 and a patterned high-k etch stop layer 114P positioned between conductive contact 132 and the outermost sidewall spacer 112, wherein an outer side surface 114O of the patterned high-k etch stop layer 114P contacts the conductive contact 132 and an upper surface 114U of the patterned high-k etch stop layer 114P is positioned at a level relative to an upper surface 102S of the substrate 102 that is below a level of the bottom surface 124S of the gate cap layer 124.

In more detailed embodiments of the device 100, a bottom surface 114B of the patterned high-k etch stop layer 114P contacts an upper surface 111S of the epi semiconductor material, and an inner surface 114I of the patterned high-k etch stop layer 114P contacts an outer surface of the outermost sidewall spacer 112. In cases where the liner layer 113 is employed, the bottom surface 114B of the patterned high-k etch stop layer 114P contacts an upper surface of liner layer 113 and a bottom surface of the liner layer 113 contacts the upper surface of the epi semiconductor material in the source/drain region. Additionally, in such a case, the inner surface 114I of the patterned high-k etch stop layer 114P contacts the liner layer 113 and the liner layer 113 contacts an outer surface of the outermost sidewall spacer 112.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Note that the use of terms, such as “first,” “second,” “third” or “fourth” to describe various processes or structures in this specification and in the attached claims is only used as a shorthand reference to such steps/structures and does not necessarily imply that such steps/structures are performed/formed in that ordered sequence. Of course, depending upon the exact claim language, an ordered sequence of such processes may or may not be required. Accordingly, the protection sought herein is as set forth in the claims below.

What is claimed:

1. A method of forming a transistor above a semiconductor substrate, said transistor comprising a gate structure and an epitaxially formed semiconductor material in source/drain regions of said transistor, wherein the method comprises:
forming a patterned high-k etch stop layer above said epitaxially formed semiconductor material in said source/drain regions of said transistor;
forming at least one layer of insulating material above said patterned high-k etch stop layer;
performing at least one contact opening etching process to form at least one contact opening in said at least one layer of insulating material, wherein said patterned high-k etch stop layer acts as an etch stop during said at least one contact opening etching process;
performing an etching process to remove portions of said patterned high-k etch stop layer exposed by said at least one contact opening; and
forming a conductive contact in said at least one contact opening that is conductively coupled to said epitaxially formed semiconductor material in at least one of said source/drain regions of said transistor.

2. The method of claim 1, wherein forming said patterned high-k etch stop layer above said epitaxially formed semiconductor material in said source/drain regions of said transistor comprises:
forming a high-k etch stop layer above said gate structure and above said epitaxially formed semiconductor material in said source/drain regions of said transistor;
forming a sacrificial layer of material above said gate structure and said high-k etch stop layer;
reducing a thickness of said sacrificial layer of material so as to expose a portion, but not all, of said high-k etch stop layer, said reduced-thickness sacrificial layer of material having an upper surface; and
performing at least one first etching process to remove at least the portions of said high-k etch stop layer positioned above said upper surface of said reduced-thickness sacrificial layer to thereby form said patterned high-k etch stop layer.

3. The method of claim 2, wherein, after performing said at least one first etching process, the method further comprises removing any residual portions of said reduced-thickness sacrificial layer of material.

4. The method of claim 3, wherein, after removing said residual portions of said reduced-thickness sacrificial layer of material, the method further comprises forming at least one layer of insulating material above said patterned high-k etch stop layer.

5. The method of claim 1, further comprising:
prior to forming said patterned high-k etch stop layer, forming a liner layer on said epitaxially formed semiconductor material and on sidewall spacers positioned adjacent said gate structure;
forming a non-patterned layer of said high-k etch stop layer on said liner layer; and
patterning said non-patterned layer of said high-k etch stop layer so as to thereby form said patterned high-k etch stop layer.

6. The method of claim 1, wherein said patterned high-k etch stop layer is formed on and in contact with said epitaxially formed semiconductor material in said source/drain regions.

7. The method of claim 1, wherein said patterned high-k etch stop layer is comprised of one of aluminum oxide or hafnium oxide.

8. The method of claim 5, further comprising performing an etching process through said patterned high-k etch stop layer so as to remove exposed portions of said liner layer and thereby expose portions of said epitaxially formed semiconductor material in said source/drain regions.

9. The method of claim 1, wherein said gate structure is one of a final gate structure or a sacrificial gates structure.

10. A method of forming a transistor above a semiconductor substrate, said transistor comprising a gate structure, sidewall spacers and an epitaxially formed semiconductor material in source/drain regions of said transistor, wherein the method comprises:
forming a high-k etch stop layer above said gate structure and above said epitaxially formed semiconductor material in said source/drain regions of said transistor;
forming a sacrificial layer of material above said gate structure and said high-k etch stop layer;
reducing a thickness of said sacrificial layer of material so as to expose a portion, but not all, of said high-k etch stop layer, said reduced-thickness sacrificial layer of material having an upper surface;
performing at least one first etching process to remove at least the portions of said high-k etch stop layer positioned above said upper surface of said reduced-thickness sacrificial layer, thereby forming a patterned high-k etch stop layer;
after performing said at least one first etching process, removing any residual portions of said reduced-thickness sacrificial layer of material;
after removing said residual portions of said reduced-thickness sacrificial layer of material, forming at least one layer of insulating material above said patterned high-k etch stop layer;
performing at least one second etching process to form at least one contact opening in said at least one layer of insulating material, wherein said patterned high-k etch stop layer acts as an etch stop during said at least one second etching process;
performing a third etching process to remove portions of said patterned high-k etch stop layer exposed by said at least one contact opening; and
forming a conductive contact in said at least one contact opening that is conductively coupled to said epitaxially formed semiconductor material in at least one of said source/drain regions of said transistor.

11. The method of claim 10, further comprising:
prior to forming said high-k etch stop layer, forming a liner layer on said epitaxially formed semiconductor material and on sidewall spacers positioned adjacent said gate structure;
forming said high-k etch stop layer on said liner layer; and
performing at least one etching process using said liner layer as an etch stop layer so as to thereby form said patterned high-k etch stop layer.

12. The method of claim 11, further comprising performing an etching process through said patterned high-k etch stop layer so as to remove exposed portions of said liner layer and thereby expose portions of said epitaxially formed semiconductor material in said source/drain regions.

13. A method of forming a transistor above a semiconductor substrate, said transistor comprising a gate structure and a plurality of source/drain regions, wherein the method comprises:
forming a patterned high-k etch stop layer above said source/drain regions of said transistor;
forming at least one layer of insulating material above said patterned high-k etch stop layer;
performing at least one contact opening etching process to form at least one contact opening in said at least one layer of insulating material, wherein said patterned high-k etch stop layer acts as an etch stop during said at least one contact opening etching process;
performing an etching process to remove portions of said patterned high-k etch stop layer exposed by said at least one contact opening; and
forming a conductive contact in said at least one contact opening that is conductively coupled to at least one of said source/drain regions of said transistor.

14. A transistor device comprising a plurality of source/drain regions, the device comprising:
a gate structure formed above a semiconductor substrate;
a gate cap layer positioned above at least a portion of said gate structure, said gate cap layer having a bottom surface;
an outermost sidewall spacer formed adjacent a side of said gate structure;
a conductive contact that is conductively coupled to one of said source/drain regions; and
a patterned high-k etch stop layer positioned between said conductive contact and said outermost sidewall spacer, wherein an outer side surface of said patterned high-k etch stop layer contacts said conductive contact and an upper surface of said patterned high-k etch stop layer is positioned at a level relative to an upper surface of said semiconductor substrate that is below a level of said bottom surface of said gate cap layer.

15. The device of claim 14, wherein a bottom surface of said patterned high-k etch stop layer contacts an upper surface of said source/drain regions.

16. The device of claim 15, wherein an inner surface of said patterned high-k etch stop layer contacts an outer surface of said outermost sidewall spacer.

17. The device of claim 14, further comprising an epi semiconductor material that is formed as part of said source/drain regions.

18. The device of claim 17, wherein a bottom surface of said patterned high-k etch stop layer contacts an upper surface of said epi semiconductor material.

19. The device of claim 18, wherein an inner surface of said patterned high-k etch stop layer contacts an outer surface of said outermost sidewall spacer.

20. The device of claim 14, wherein the device further comprises a liner layer positioned between said patterned high-k etch stop layer and said outermost sidewall spacer.

21. The device of claim 20, wherein a bottom surface of said patterned high-k etch stop layer contacts an upper surface of said liner layer and a bottom surface of said liner layer contacts an upper surface of said source/drain regions.

22. The device of claim 21, wherein an inner surface of said patterned high-k etch stop layer contacts said liner layer and said liner layer contacts an outer surface of said outermost sidewall spacer.

23. The device of claim 20, further comprising an epi semiconductor material that is formed as part of said source/drain regions.

24. The device of claim 23, wherein a bottom surface of said patterned high-k etch stop layer contacts an upper surface of said liner layer and a bottom surface of said liner layer contacts an upper surface of said epi semiconductor material.

25. The device of claim 24, wherein an inner surface of said patterned high-k etch stop layer contacts said liner layer and said liner layer contacts an outer surface of said outermost sidewall spacer.

26. The device of claim 23, wherein an inner surface of said patterned high-k etch stop layer contacts an outer surface of said outermost sidewall spacer.

27. The device of claim 14, wherein said conductive contact is comprised of a barrier layer and the outer side surface of said patterned high-k etch stop layer contacts said barrier layer.
